(19) United States
(12) Patent Application Publication
(10) Pub. No.: US 2012/0106103 A1
(43) Pub. Date: May 3, 2012

(54) RADIO FREQUENCY ENERGY HARVESTING ENCLOSURE FOR RADIO FREQUENCY CONNECTED DEVICES

(76) Inventor: Tanios Nohra, Broadview Heights, OH (US)

(21) Appl. No.: 13/163,707

(22) Filed: Jun. 19, 2011

Related U.S. Application Data
(60) Provisional application No. 61/357,590, filed on Jun. 23, 2010.

(51) Int. Cl. H05K 7/00

(52) U.S. Cl. 361/752

(57) ABSTRACT

A Radio frequency energy harvester enclosure and protective enclosure for Radio Frequency connected devices that harvests and recycles some of the transmitted Radio Frequency energy for the activation of an application circuit, or to additionally charge a storage component.

### RELATED U.S. APPLICATION DATA

Provisional patent application No. 61/357,590 filed Jun. 23, 2010.

### FIELD OF THE INVENTION

This invention relates to an enclosure for radio frequency (hereinafter referred to as “RF”) connected devices, such as cellular phones, personal electronic tablet computers, and similar electronic devices, that contains a RF energy harvester. More particularly, this invention pertains to harvesting RF energy and converting it to direct current (hereinafter referred to as “DC”) electrical energy for later use by an application circuitry located either within or on the enclosure of the RF connected device, such as displaying light-emitting images.

### BACKGROUND

Radio Frequency (RF) connected devices such as cellular phones, personal electronic tablet computers, and similar devices use electromagnetic waves to communicate with base-stations that exchange information through RF energy. During such communication period, these devices send and receive RF energy to establish a communication link. This power of RF energy during communication ranges approximately from 32 μW to 1 W peak power.

It is recognized in the art that the RF energy is sometimes a health risk, and attempts have been made to limit the exposure of the user's head to RF energy. U.S. Patent Application Publication 2010/0113111, to Alfred Wong, et al., describes an apparatus to redirect RF energy from the device away from the user's head. The present invention attempts to avoid the health risks associated with RF energy by harvesting some of the RF energy and keeping it contained.

It is also recognized in the art that RF energy can be harvested and converted into DC electricity. Applications of such systems are known in biomedical implants, in order to avoid health risks associated with batteries. U.S. Patent Application Publication 2009/0152954, to Triet Tu Le, et al., describes a RF harvesting circuit with a voltage doubler rectifier circuit. The present invention obtains RF harvesting results for mobile RF connected devices.

Likewise, stylized aftermarket cellular phone cases and cases for other RF devices, such as iPod Touch® or iPad®, are popular for users to personalize their devices. The present invention supplements the options that are available to users to customize the appearance of their devices by displaying lighted images or designs. Such images or designs can also have intermittent lighting patterns according to the transmitted RF energy activity that is occurring with the device.

A primary feature of the present invention is an energy harvesting enclosure, such as a cellular phone protective case, having the ability to capture some of the transmitted RF energy, and recycle it to DC electric power, without affecting the manufacturers' intended functionality of the device operation. The harvested power and resulting voltage is derived from capturing RF energy within the existing transmitted RF field created during mobile device to base-station communication activity. Examples of base-station communication activities include, but are not limited to, incoming and outgoing calls, text messaging, and interne browsing.

Accordingly, the proposed invention harvests some of the transmitted RF energy during transmission periods while an RF connected device is in communication with a base station, and recycles it into DC power. This is accomplished in order to activate an attached or detached application circuitry. Examples of application circuitry include, but are not limited to, light-emitting devices such as light-emitting diodes, one-pixel LCD, organic LEDs, etc. Likewise, the harvested and recycled RF energy can be used to charge a storage component such as rechargeable battery or super-capacitor for a later use of the stored power.

### SUMMARY OF THE INVENTION

To address the current trends of customizing and personalizing RF connected devices such as cell phones and personal electronic tablet computers, a system for harvesting RF energy and converting it into DC power to activate a light-emitting device, is provided. The system includes an enclosure for a portable RF connected device, with the enclosure comprising a first end at a first longitudinal edge of the device opposite a second end at a second longitudinal edge of the device. As well as a body section having a first side on the back of the device that is opposite the second side of the device where a screen is located. The enclosure also comprises an interior surface of the first side that is facing inward on the device toward the battery, and an exterior surface of the first side that is facing outward toward the device's outer environment. Furthermore, a RF energy harvesting antenna is located on the interior surface of the first side of the device enclosure, as well as a RF to DC power conversion circuit located on the interior surface of the first side of the device enclosure. Additionally, a conditioning circuit located on the interior surface of the first side of the device enclosure. Finally, an electric application load is located on a surface of the first side of the device enclosure. This application load is a light-emitting device. The light emitting device could be designed in such a way to depict a visual image. In addition to a light-emitting device, the enclosure of a RF connected device of is further comprising a charge storage component.

According to another embodiment of the invention, the enclosure of a RF connected device of comprises a first piece and a second piece, that mechanically fasten, with an electrical interface between the first piece and second piece. In this embodiment, the RF harvesting antenna, RF to DC conversion circuit, and conditioning circuit are located on the first piece, whereas the electric application load, in the form of a light-emitting device, is located on the second piece. The electrical interface between the first and second piece allow the RF harvesting antenna, RF to DC conversion circuit, and conditioning circuit to provide power to the application load on the second piece.

In each of the embodiments of the present invention, the RF energy harvesting multiband antenna has a an output impedance that is substantially equal to the complex conjugate input impedance of the RF to DC power conversion circuit at the center frequency of the bands of operation for the RF connected device.

Also, the RF energy harvesting multiband antenna has a surface placed at a critical distance to the metallic surface on the interior of the RF connected device. The RF energy harvesting multiband antenna is on the same plane as the device antenna, which is parallel to the broad-side, back surface of the device. If the RF energy harvesting multiband antenna is not on the same plane as the device antenna, then it is located on a plane that is within a range of 1 mm to 5 mm from the plane of the device antenna.

In any embodiment of the present invention, the RF energy harvesting multiband antenna is made of either a flexible substrate or a rigid substrate. This application is specific to the RF device design and materials.

In yet another embodiment of the present invention, the enclosure of the RF connected device comprises an intermittent flashing light-emitting device that flashes in reaction to the transmitted power level communication activities of the RF connected device.

According to a final embodiment of the present invention, there is a method for displaying light-emitting images on an enclosure for RF connected devices comprising a RF energy harvesting antenna located on an interior surface of the device enclosure, a RF to DC power conversion circuit located on the interior surface of the device enclosure, a conditioning circuit located on the interior surface of the device enclosure, and an electric application load in the form of a light-emitting device located on the exterior surface of the device enclosure.

### BRIEF DESCRIPTION OF THE DRAWINGS

FIG. 1A shows a protective cellular phone case with a RF energy harvester antenna and application circuit located on the interior surface of the enclosure.

FIG. 1B shows a perspective view of an exposed RF energy harvester mounted on the interior surface of the protective enclosure.

FIG. 2 shows a cross section of the of a protective cellular phone enclosure design including an embedded RF energy harvester mounted on the interior surface.

FIG. 3 shows a side view of the protective enclosure and the embedded RF energy harvester and application circuit.

FIG. 4 shows an illustration of the radio frequency energy harvester and application circuit embedded in the protective enclosure mounted on a cellular phone.

FIG. 5 shows a block diagram of the RF energy harvester and the application circuit, such as a light-emitting device.

FIG. 6 shows the electrical block diagram including voltage doubler circuit.

FIGS. 7A & 7B show the Smith chart plot of the multiband harvesting antenna output impedance and the RF to DC power conversion circuit input impedance on the same chart, at the PCS (1850-1910 MHz) and the Cellular (824-849 MHz) frequency bands.

FIG. 8 shows an exemplary protective enclosure comprising an interchangeable first piece that has an electrical and mechanical interface to a second piece, whereas the first piece contains a light emitting logo, or symbol on the exterior back surface of the enclosure.

FIG. 9 shows an exemplary protective enclosure for a cell phone, comprising two pieces slide-lock interface and user customizable section contain a light emitting logo, or symbol on the exterior back surface of the customizable section.

FIG. 10 shows a cell phone protective enclosure having four LEDs being activated by the RF energy harvester.

### DETAILED DESCRIPTION OF THE INVENTION

The present invention is described herein with reference to a variety of RF connected device enclosures, such as those for cell phones and personal electronic tablet computers. The detailed description set forth below, in association with the drawings and diagrams, is intended as a description of exemplary embodiments of the present invention and does not represent the only embodiments in which the present invention can be practiced. The detailed description includes specific details for the purpose of providing an understanding of the present invention, and is not limiting in any way. Those skilled in the art will recognize that the invention can be practiced in various applications while deviating from the specific details described herein.

The following defined terms are of exemplary terms used within this disclosure. Except where noted otherwise, variants of all terms, including singular or plural forms, fall within each exemplary term meaning:
I. “Enclosure” as used herein means, but is not limited to the protective plastic case that is the hardware of a cellular phone, gaming device, music player, personal electronic tablet computer, etc.
II. “Radio Frequency connected” or “RF connected” as used herein, includes but is not limited to, a communicative relationship between devices or circuits via electromagnetic waves.
III. “RF to DC power conversion circuit,” as used herein means a diode rectifier circuit, voltage doubler circuit, full-wave rectifier circuit, or similar solid state rectifier components and integrated circuit.
IV. “RF energy harvester,” as used herein means a RF harvesting antenna and RF to DC power conversion circuit.

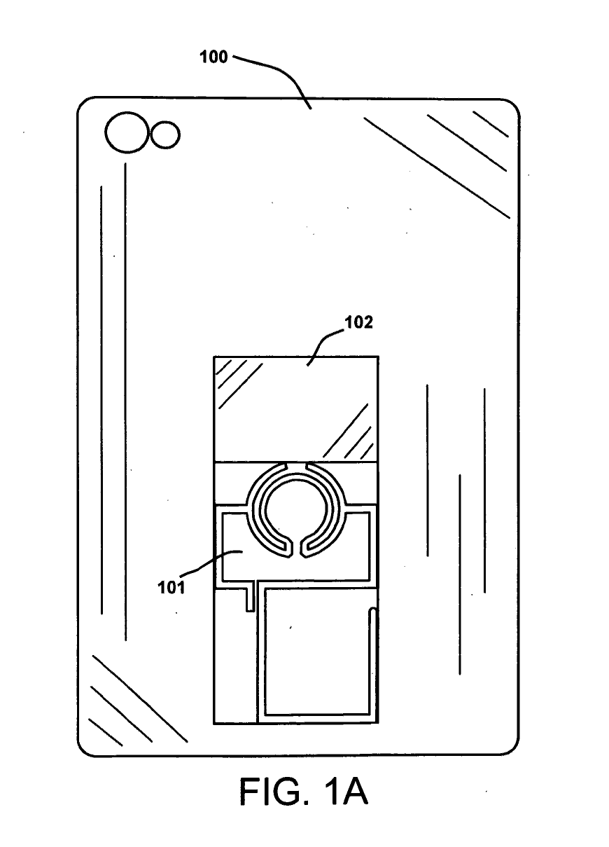

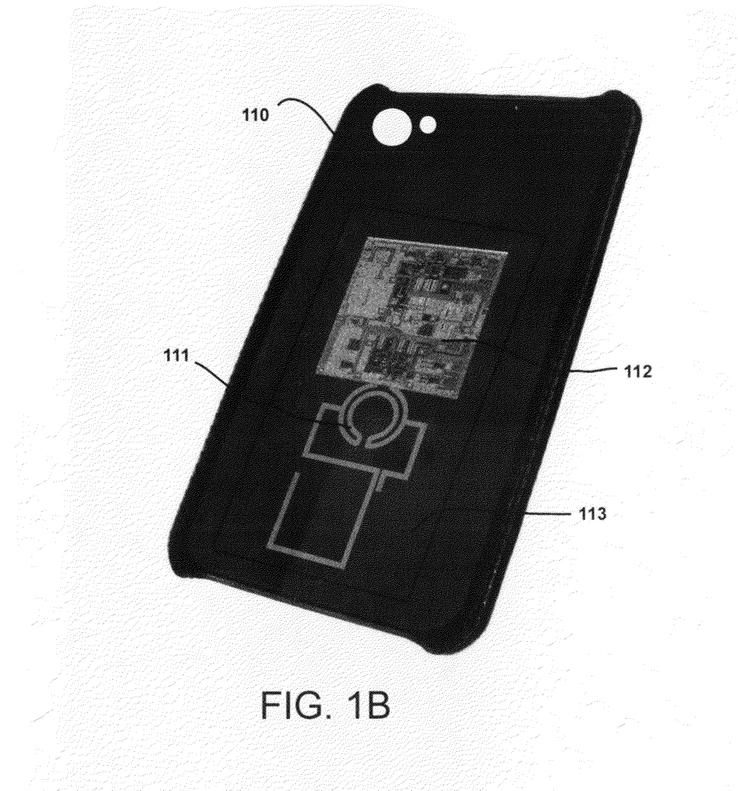

FIG. 1A illustrates the interior of a RF connected device enclosure 100 with a RF harvesting antenna 101 and application circuit 102. FIG. 1B illustrates a RF connected device enclosure 110 made of a plastic such as ABS or similar material. RF energy is captured by means of RF harvesting antenna 111 and recycled by means of RF to DC power conversion circuit 112. The RF energy harvester 111 and the application circuits 112 are populated on printed circuit board 113 using a thin flexible substrate or on a thin rigid printed circuit board substrate. The enclosure 110 is similar in appearance to a cellular phone external protective case.

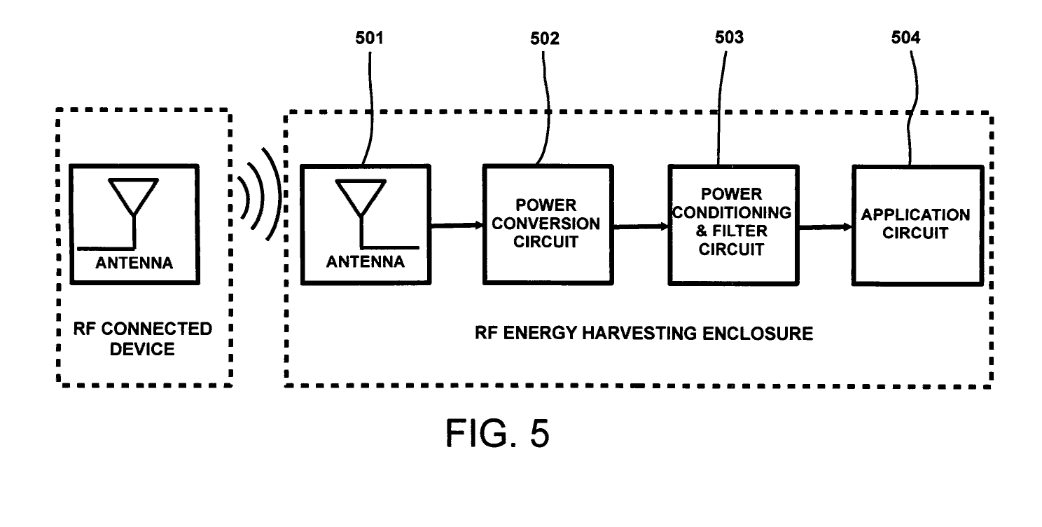

FIG. 5 illustrates the block diagram for a RF energy harvester system. RF energy is captured by the antenna structure 501 and recycled by RF to DC power conversion circuit 502 and a power conditioning and filter circuit 503. The combination of these blocks supply the required power to an application circuitry 504, such as a light-emitting device. The RF to DC power conversion circuit 502 is made of small package surface mount zero bias Schottky detector diodes such as the HSMS-286x series or similar rectifier devices or integrated circuit and devices, and a filter circuit.

The application circuit 504 can be made from active devices, passive devices, or a combination of active and passive devices. Such active and passive devices include, but are not limited to, light-emitting diodes, super capacitors, solid state batteries, rechargeable batteries, and electronic circuits. The application circuit 504 maybe embedded in the enclosure or it can be an auxiliary apparatus that is either attached or detached from the enclosure.

The presented RF energy harvester 501 does not require an impedance matching network. However, an additional impedance matching network may be utilized to broaden the impedance match of the antenna structure 501 to the RF to DC power conversion circuit 502. The various components and structures, which are integral to the enclosure, convert mainly some of the transmitted RF energy to a DC power and voltage for activation of a single or multiple application circuits.

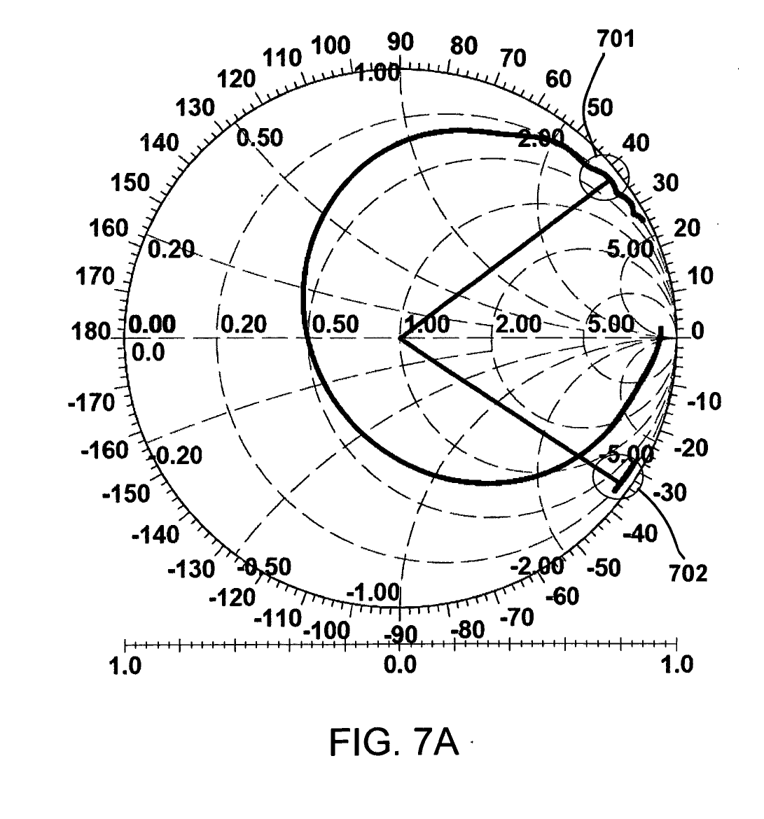

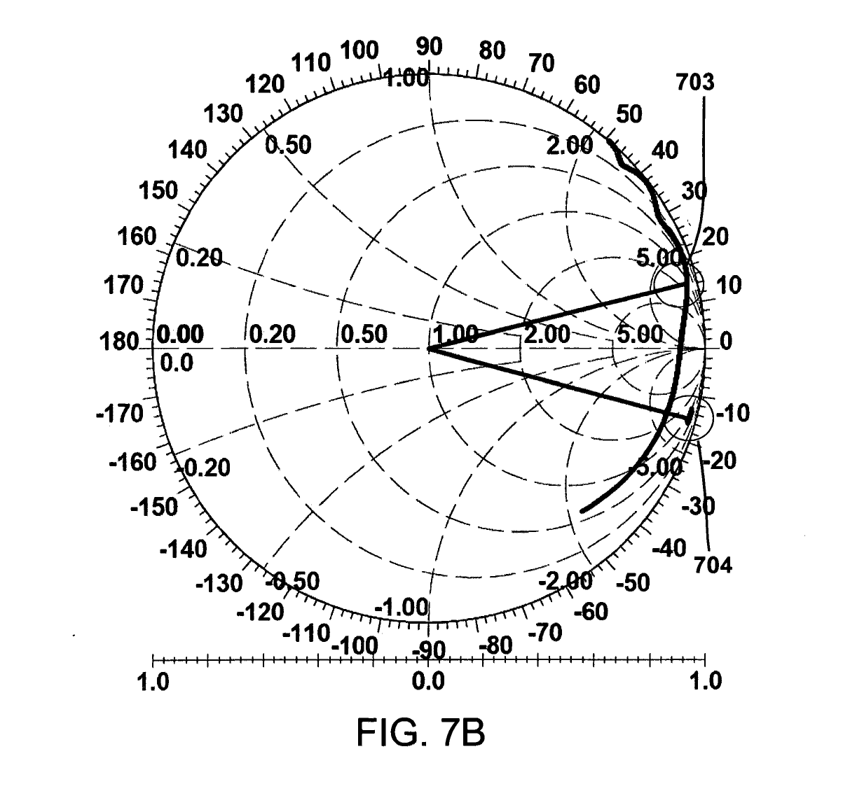

Several types of harvesting antenna structures 501 may be employed. A key aspect of the harvesting antenna is its impedance value. The harvesting antenna 501 impedance must be equal or near the complex conjugate impedance of that of the voltage doubler 502, 602 input circuit, Z (Antenna)=Z*(voltage doubler), as illustrated in FIGS. 7A and 7B. The harvesting antenna 501 combined with the RF to DC power conversion circuit 502 form a resonant network.

In addition to specific antenna design practice, the embedded harvesting antenna structure is configured utilizing the enclosure material, such as ABS plastic or other enclosure material, thickness and electrical properties such as Dielectric Constant to achieve the required impedance value 701 and 703. The embedded harvester antenna design also accounts for the distance 204 between the harvesting antenna structure 207 and the internal hardware 202 of the RF connected device. Additionally, the harvester antenna design accounts for the thickness of the enclosure material 206 that surrounds harvesting antenna structure 207, in order to tune the harvesting antenna for optimum RF energy capturing and improve the system efficiency.

FIGS. 7A and 7B show simulated data points on a Smith Plot, of the antenna structure impedance 701, 703 and the RF to DC power conversion circuit impedance 702, 704 at various frequencies. In consideration of the range of frequency bands utilized for cellular phones, the harvesting antenna output impedance 701, 703 is substantially near the complex conjugate of the RF to DC power conversion circuit input impedance 702, 704 at the average frequency of each band.

The RF harvester employs and makes use of the RF to DC power conversion circuit 502 and the rectifier diodes junctions capacitance 602 to form the resonant circuit and impedance match 701, 702, such that the energy transfer to the RF to DC power conversion circuitry 502 and application circuitry 504 is optimized without the use of any matching network circuit.

Prior art teaches that an additional impedance matching circuit is required to maximize power transfer. According to the detailed description above, the present invention does not require a matching circuit to maximize power transfer, and therefore reduces the overall cost of the RF harvester. A matching network maybe used to further improve the power transfer between the harvester antenna structure and the RF to DC power conversion circuit, but is not necessary for satisfactory operation.

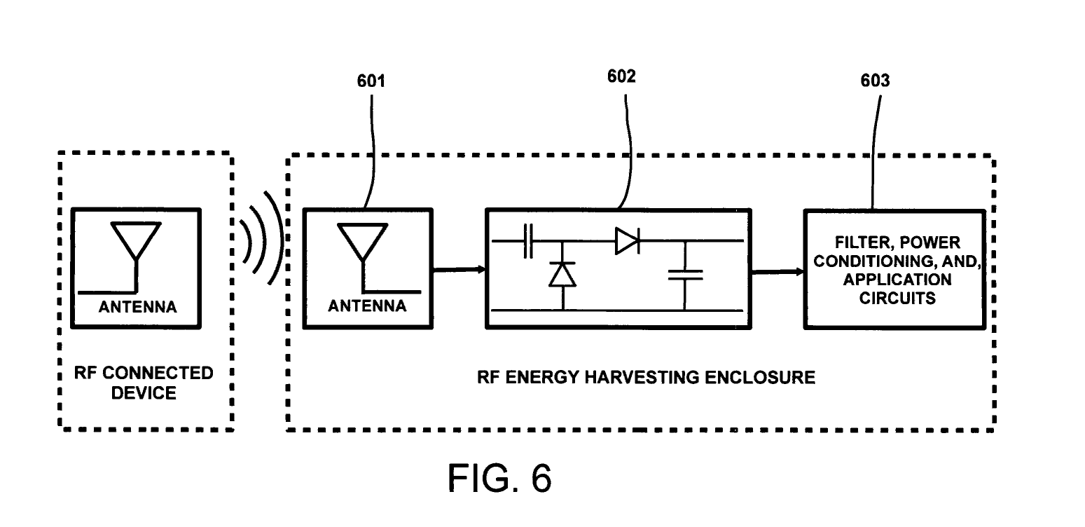

As illustrated in FIG. 6, the RF to DC power conversion circuit 602 is made of a voltage doubler circuit or full wave rectifier. The output voltage can be increased by cascading more than one voltage doubler stage. The signal conditioning block 603 may include a voltage regulator and a filter circuit.

In an embodiment that employs more than one voltage doubler stage, the harvesting antenna output impedance must be tuned to the complex conjugate of the cascaded voltage doublers input impedance.

To maximize the voltage amplitude at the input of the RF to DC power conversion circuit, a virtual L-C resonant circuit is formed by the antenna inductive impedance and the RF to DC power conversion circuit diodes junctions capacitance.

The number of voltage doubler stages used has significant impact on the harvester efficiency. It will change the RF to DC power conversion circuit equivalent input capacitance. If more voltage doubler stages are used, the RF to DC power conversion circuit junction and parasitic capacitance components vary, and therefore effecting the impedance match and the resonance frequency. The presented patent utilizes but not limited to one voltage doubler stage as the RF to DC power conversion circuit FIG. 6.

The application circuit and load impedance and resistance have an effect on the overall harvester efficiency. The presented enclosure is designed to accommodate the integrated harvesting antenna, RF to DC power conversion circuit, filter and power conditioning circuit, and the application circuitry. The presented methodology is an illustration of an exemplary enclosure and is general. One with skill in the art will recognize that different methodologies, combinations of elements, and materials maybe used.

The harvesting antenna structure placement, orientation, height, and position with respect to the transmitting antenna of the RF connected device, such as a cellular phone, is controlled during the design stage to maximize the energy harvested and minimize the effect on the Radio Frequency connected device mode of operation.

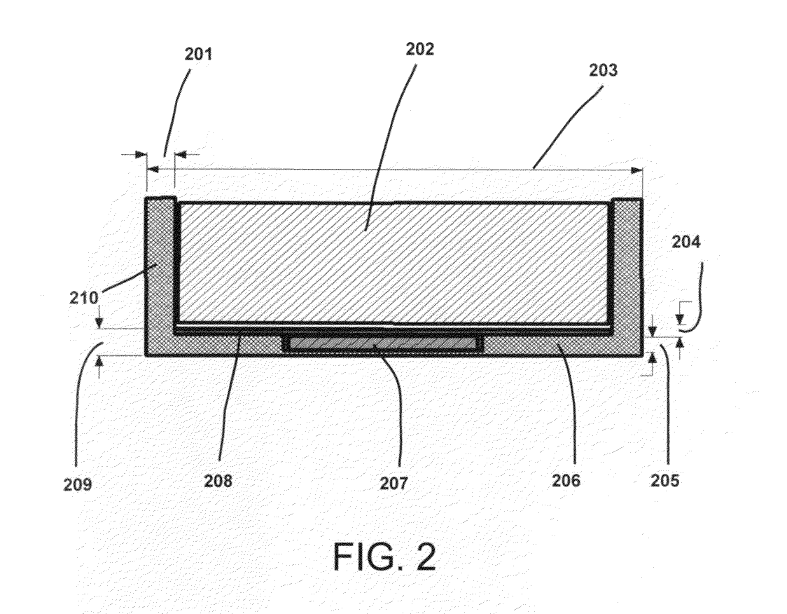

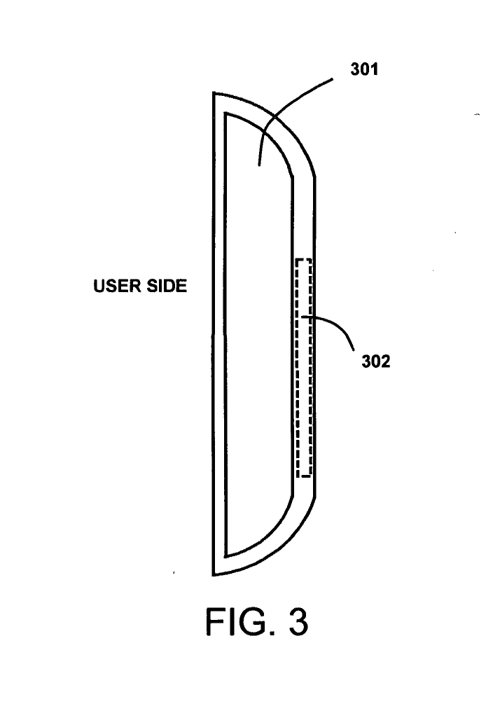

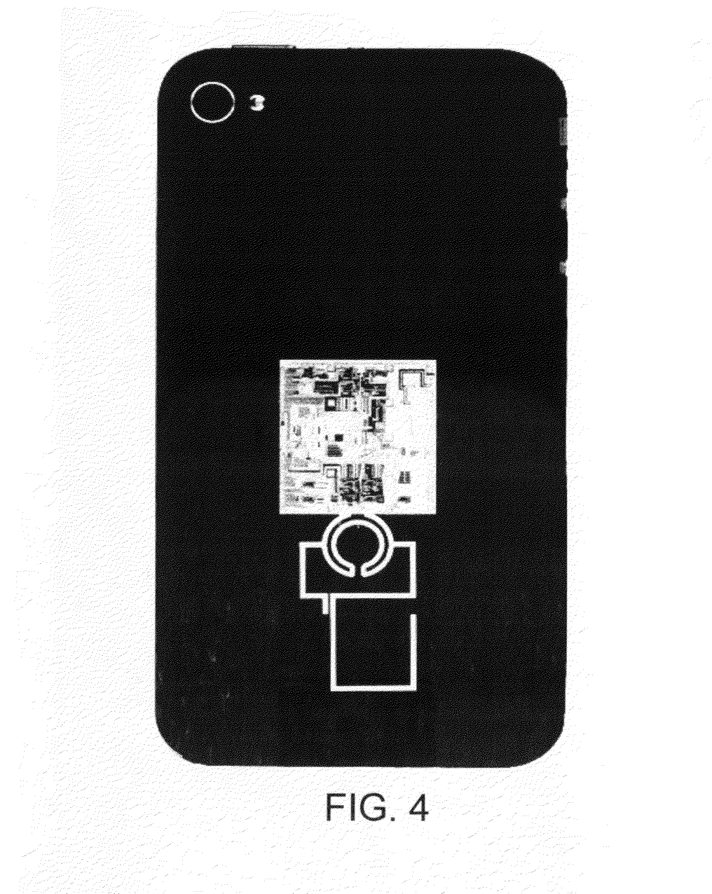

Shown in FIG. 2 is a cross-section view of the presented plastic enclosure 210. The enclosure width 203 varies and could be different for each device and is designed to fit on the RF connected device just like in any typical protective case. In an exemplary embodiment, the enclosure wall thickness 201 ranges from about 1.5 mm to 2.5 mm. The enclosure's broad side thickness 209 ranges from about 2.5 mm to 4 mm including the cover layer 208. The enclosure's broad side thickness 209 is designed to accommodate the integrated harvester and application circuit.

The presented RF to DC power conversion circuit and topology has a direct effect on the system efficiency and impedance matching. The RF to DC power conversion circuit input capacitance is used in conjunction with the antenna output inductance to form the high Q resonant circuit. The embedded harvester 207 and application circuit thickness 205 is about 1.5 mm. The exemplary distance 204 between the Radio Frequency connected device back 202 and the harvester, range from 1.5 mm to 5 mm and it's critical to the harvester antenna operation and impedance. It affects the harvester efficiency.

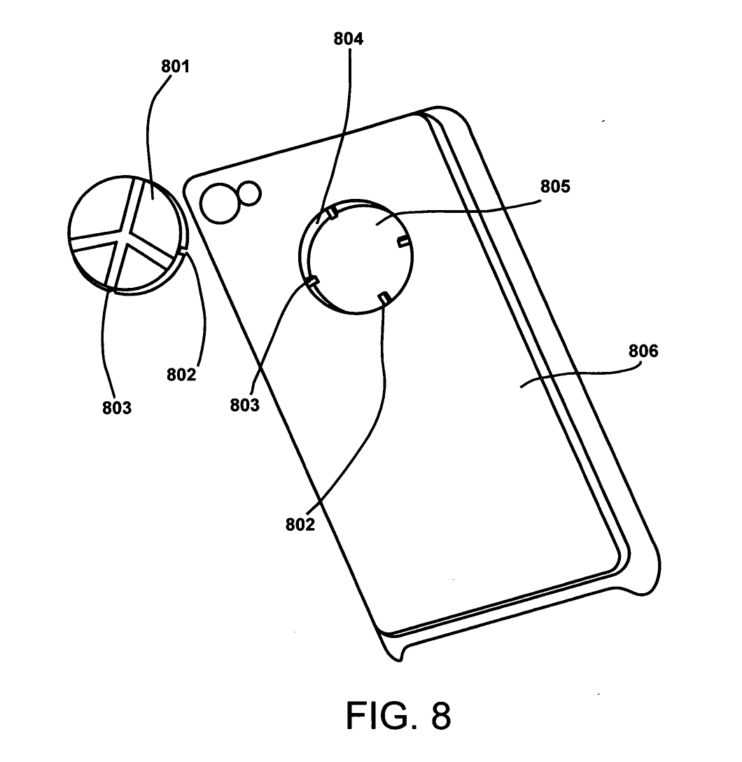

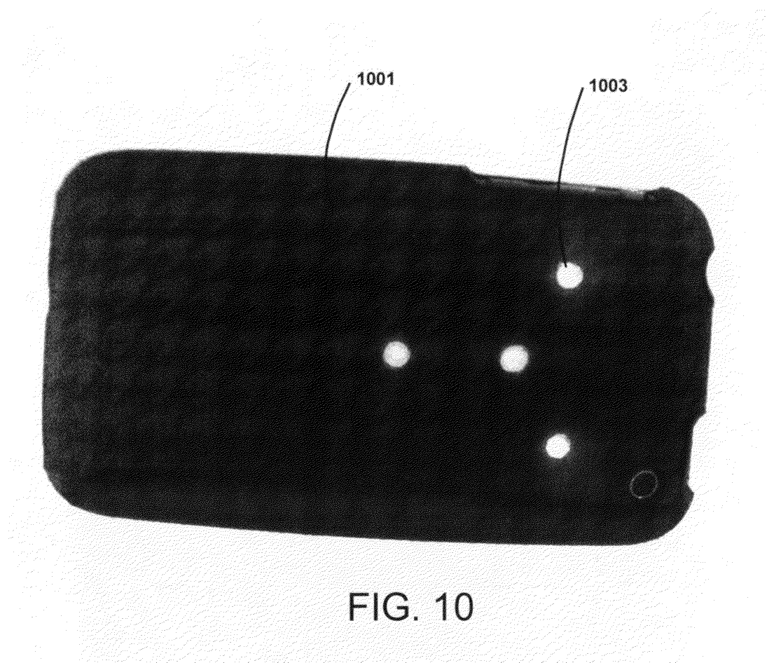

As illustrated in FIG. 8 and FIG. 10, an embodiment of the presented enclosure including RF harvester pertains to a personalized and customizable protective cover for a person's RF connected device, such as a cellular phone. The enclosure 806 has an interface to lock, hold, and supply electrical power to a logo or icon 801. The logo or icon section 801 may be of any shape, such as square, circle, or octagon. The logo or icon section 801 may incorporate any design such as a drawing, image, or symbol. The customizable protective cover 806 comprises an opening 805 to house an inter-changeable logo or icon 801. FIG. 8 shows a twist or push-to-lock design interface that incorporates a mechanical lock 802 and electrical contacts 803. The thickness 804 of the presented enclosure varies to suit the logo or icon mechanical and electrical requirements.

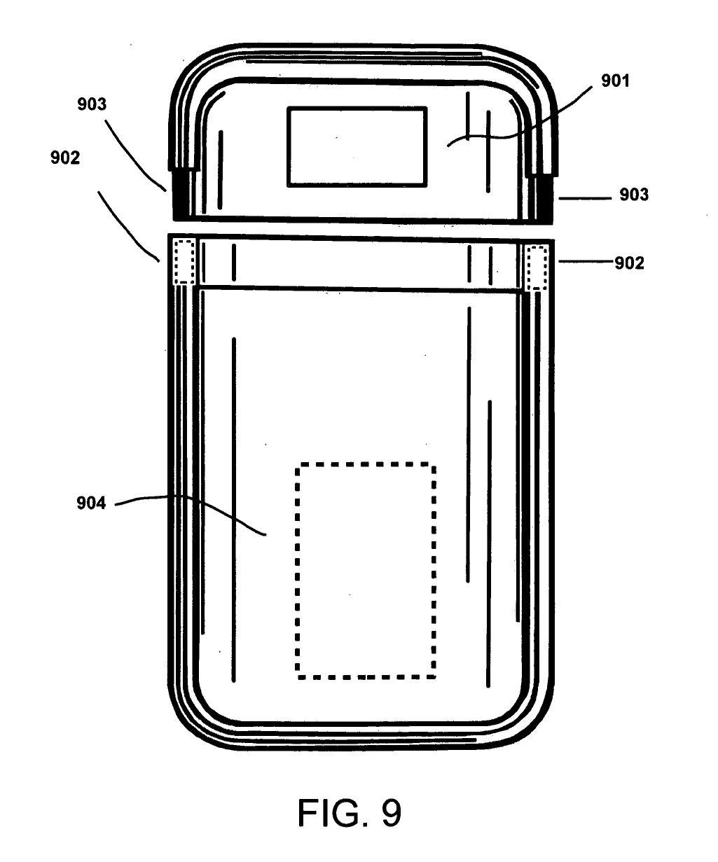

FIG. 9 shows another embodiment of a two pieces slide-lock interface. The user customizable section 901 of the enclosure is inter-changeable and contains a logo, icon, or any application circuit, such as a light-emitting device. The larger enclosure section 904 contains the RF energy harvester and the power conditioning circuit. The two separate sections 901, 904 of the enclosure join together by means of an electrical interface 903 and a mechanical interface 902. A primary feature of the user customizable section 901 of the enclosure is the ability of customizing a single enclosure using multiple logo, icon, or design options. The RF connected device user is able to have one enclosure that is quickly modifiable and customizable. This is accomplished by replacing only the smaller section 801, 901 containing a logo or icon with another that incorporates a different design or function. Interchangeability of the logo or icon section 801, 901 is possible by incorporating the same mechanical interface 802, 902 and electrical interface 803, 903, as the larger enclosure section 806, 904. Therefore, the user creates a new customized look and a new enclosure design or function without acquiring a new enclosure altogether.

The logo or icon section 801, 901 may or may not incorporates electrical components. In one embodiment the logo or icon section 801, 901 only incorporates the graphic design. The light-emitting device, such as an LED, is incorporated and embedded in the larger enclosure section 806, 904. The light-emitting device is placed in the larger enclosure section cavity 805, and mounted between the internal hardware of the RF device and the logo or icon section 801, 901 such that emitted light shines through the logo or icon to create an image for visual stimulation.

Likewise, it can be recognized and appreciated in an embodiment where a logo or icon is directly incorporated on a singular and unitary RF device enclosure, as apparent in FIG. 10. In such an embodiment, the logo or icon is not interchangeable from the enclosure as a whole.

In FIG. 10 a cellular phone enclosure 1001 is embedded with light-emitting diodes (LEDs) 1003. The LED excitation and illumination is facilitated through the harvested energy, without the use of a battery or any form of plugged or wired power source. The enclosure 1001 may include single or multiple antenna structures, RF to DC power conversion circuits, storage devices such as super-capacitor, electronics devices, and integral LED(s) 1003 as visual signaling devices. The light-emitting diodes 1003 are suitable for visual signaling of an incoming communication, such as phone calls or text messages, when the cellular phone is screen side down and the ringer is turned off. Likewise, the illuminated LEDs 1003 provide visual stimulation of their own as in FIG. 10 or through illuminating art such as an icon or logo 801, as in FIG. 8. The illumination can be constant light, or flashing light that is synchronized to the cellular phone base-station communication activities of the attached RF connected device.

Where the RF energy harvester is used to directly power the LED(s) 1003 to decorate a protective case logo or icon 801, the RF connected device transmitted power levels and operation modes affect the brightness level of the LED(s) 1003 and is an indication of the transmitted power level. Light-emitting diode 1003 brightness is directly proportional to the peak power level of the radio frequency wave being transmitted by the Radio Frequency connected device. In another embodiment where conditioning circuit and charge storage device is used, the brightness level of the LED(s) is controlled.

In any every embodiment of the present invention, all or some of the electronic circuitry, including the logo or icon embedded circuitry, will be powered by the RF energy harvester which is incorporated and integrated within the physical structure of the RF device protective enclosure.

The logo or icon section 801, 901 may includes batteries to power additional electronic circuitry that is triggered and controlled by the enclosure energy harvester signal and circuit. Furthermore, audible and tactile notification mechanisms, such as the ringer and vibration, can be turned of and the user will be alerted of incoming communications utilizing only the RF harvested energy to activate its integral light-emitting device on the enclosure. An obvious benefit of such method of operation results in an extension of the internal battery cycle life for the RF connected device, while continuously indicating operation of the attached device.

What is claimed is:

1. An enclosure for a portable RF connected device, the enclosure comprising:
a first end at a first longitudinal edge of the device opposite a second end at a second longitudinal edge of the device;
a body section having a first side on the back of the device that is opposite the second side of the device where a screen is located;
an interior surface of the first side that is facing inward on the device toward the battery;
an exterior surface of the first side that is facing outward toward the device's outer environment;
a RF energy harvesting antenna located on the interior surface of the first side of the device enclosure;
a RF to DC power conversion circuit located on the interior surface of the first side of the device enclosure;
a conditioning circuit located on the interior surface of the first side of the device enclosure; and
an electric application load located on a surface of the first side of the device enclosure.

2. The enclosure of a RF connected device of claim 1, further comprising a light-emitting device on the exterior surface.

3. The enclosure of a RF connected device of claim 2, further comprising a visual image on the exterior surface of the first side of the device enclosure.

4. The enclosure of a RF connected device of claim 1, further comprising a charge storage component.

5. The enclosure of a RF connected device of claim 1, further comprising:
a first piece and a second piece, that mechanically fasten;
an electrical interface between the first piece and second piece;
the RF harvesting antenna, RF to DC power conversion circuit, and conditioning circuit located on the first piece;
the electric application load located on the second piece;
the electrical interface between the first and second piece allow the RF harvesting antenna, RF to DC conversion circuit, and conditioning circuit to provide power to the application load on the second piece.

6. The enclosure of a RF connected device of claim 1, further comprising an embedded RF energy harvesting multiband antenna having an output impedance that is substantially equal to the complex conjugate input impedance of the RF to DC power conversion circuit at the center frequencies of the bands of operation for the RF connected device.

7. The enclosure of a RF connected device of claim 5, further comprising a RF energy harvesting multiband antenna located on the interior of the RF connected device that has a surface placed at a critical distance to the metallic surface of the internal hardware of the RF connected device, said distance in the range of 1.5 mm to 5 mm.

8. The enclosure of a RF connected device of claim 1, further comprising a RF energy harvesting multiband antenna made of a flexible substrate.

9. The enclosure of a RF connected device of claim 1, further comprising a RF energy harvesting multiband antenna made of a rigid substrate.

10. The enclosure of a RF connected device of claim 1, further comprising an intermittent flashing light-emitting device synchronized by the transmitted power level of communication activities.

11. A method for displaying light emitting images on an enclosure for RF connected devices comprising:
a RF energy harvesting antenna located on an interior surface of a first side of the device enclosure;
a RF to DC power conversion circuit located on the interior surface of the first side of the device enclosure;
a conditioning circuit located on the interior surface of the first side of the device enclosure; and
an electric application load located on the exterior surface of the first side of the device enclosure.
